(19) United States
(12) Patent Application Publication
(10) Pub. No.: US 2023/0275567 A1
(43) Pub. Date: Aug. 31, 2023

(54) FILTER DEVICE

(71) Applicant: Murata Manufacturing Co., Ltd., Nagaokakyo-shi (JP)

(72) Inventors: Seima KONDO, Nagaokakyo-shi (JP); Satoshi TANAKA, Nagaokakyo-shi (JP); Yasuhisa YAMAMOTO, Nagaokakyo-shi (JP)

(21) Appl. No.: 18/142,100

(22) Filed: May 2, 2023

Related U.S. Application Data
(63) Continuation of application No. PCT/JP2021/040267, filed on Nov. 1, 2021.

(30) Foreign Application Priority Data
Nov. 2, 2020 (JP) 2020-183776

(51) Int. Cl. H03H 9/205; H03H 9/02

(52) U.S. Cl. CPC H03H 9/205; H03H 9/02007; H03H 9/6483

(57) ABSTRACT

A filter device includes a first filter including a first input terminal, a first output terminal, a first series arm including first series arm resonators, and first parallel arms connected to the first series arm and each including a first parallel arm resonator, the first filter having a pass band in a predetermined frequency band, a second filter including a second input terminal, a second output terminal, a second series arm including second series arm resonators, and second parallel arms connected to the second series arm and each including a second parallel arm resonator, the second filter having a pass band in the predetermined frequency band, a substrate including the first and second filters, and an inductor connected between a ground terminal and a parallel arm resonator included in at least one parallel arm of the first and second parallel arms.

### CROSS REFERENCE TO RELATED APPLICATIONS

This application claims the benefit of priority to Japanese Patent Application No. 2020-183776 filed on Nov. 2, 2020 and is a Continuation application of PCT Application No. PCT/JP2021/040267 filed on Nov. 1, 2021. The entire contents of each application are hereby incorporated herein by reference.

### BACKGROUND OF THE INVENTION

### 1. Field of the Invention

The present invention relates to a filter device.

### 2. Description of the Related Art

An existing wireless communication device such as a mobile phone includes a device for filtering a specific signal. For example, Japanese Unexamined Patent Application Publication No. 11-346142 describes a surface acoustic wave device in which two ladder filters each including a plurality of SAW resonators connected in series are disposed on a piezoelectric substrate such that parallel arm resonators connected to parallel arms of each of the ladder filters are connected to ground to extract an output difference between the two ladder filters to increase the electric power handling capability.

In recent wireless communication devices, power amplifiers for amplifying the power of a signal may have a differential configuration to increase output power. Such a wireless communication device may include the surface acoustic wave device described in Japanese Unexamined Patent Application Publication No. 11-346142 to filter high-power differential signals output from the power amplifier. A ladder filter with a wider pass band generally has larger signal loss. In the surface acoustic wave device described in Japanese Unexamined Patent Application Publication No. 11-346142, each ladder circuit is defined only by resonators, and the pass band of such a ladder circuit is widened, resulting in increased signal loss. As a result, the pass band cannot be sufficiently widened.

### SUMMARY OF THE INVENTION

Preferred embodiments of the present invention provide filter devices each with a widened pass band and an increased electric power handling capability.

A filter device according to a preferred embodiment of the present invention includes a first filter including a first input terminal, a first output terminal, a first series arm connecting the first input terminal and the first output terminal and including a plurality of first series arm resonators, and a plurality of first parallel arms connected to the first series arm and each including a first parallel arm resonator, the first filter having a pass band in a predetermined frequency band, a second filter including a second input terminal, a second output terminal, a second series arm connecting the second input terminal and the second output terminal and including a plurality of second series arm resonators, and a plurality of second parallel arms connected to the second series arm and each including a second parallel arm resonator, the second filter having a pass band in the predetermined frequency band, a substrate including the first filter and the second filter, and an inductor connected between a ground terminal and a parallel arm resonator included in at least one parallel arm of the plurality of first parallel arms and the plurality of second parallel arms.

According to preferred embodiments of the present invention, it is possible to provide filter devices whose pass bands can be widened with increased electric power handling capability.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a diagram illustrating an example schematic configuration of a filter device according to a first preferred embodiment of the present invention.

FIG. 2 is a diagram illustrating an example of a circuit configuration of a filter unit according to the first preferred embodiment of the present invention.

FIG. 3A is a diagram illustrating an example of a bandpass characteristic of a ladder filter.

FIG. 3B is a diagram illustrating a bandpass characteristic of a ladder filter having a wider pass band than a pass band illustrated in FIG. 3A.

FIG. 3C is a diagram illustrating a bandpass characteristic of a ladder filter having a parallel arm resonator to which an inductor is connected.

FIG. 4 is a diagram illustrating an example of a circuit configuration of an input converter and an output converter according to the first preferred embodiment of the present invention.

FIG. 5 is a diagram illustrating an example of a layout of the filter unit, the input converter, and the output converter of a filter device according to the first preferred embodiment of the present invention.

FIG. 6 is a schematic view of a first layer of the filter unit according to the first preferred embodiment of the present invention.

FIG. 7 is a schematic view of a second layer of the filter unit according to the first preferred embodiment of the present invention.

FIG. 8 is a schematic view of a third layer of the filter unit according to the first preferred embodiment of the present invention.

FIG. 9 is a diagram illustrating a circuit configuration of a filter device according to a second preferred embodiment of the present invention.

FIG. 10 is a diagram illustrating a circuit configuration of a filter unit according to a third preferred embodiment of the present invention.

FIG. 11 is a diagram illustrating a circuit configuration of an output converter according to a fourth preferred embodiment of the present invention.

FIG. 12 is a diagram illustrating a circuit configuration of an output converter according to a fifth preferred embodiment of the present invention.

FIG. 13 is a view illustrating a layout of a filter device according to a sixth preferred embodiment of the present invention.

FIG. 14 is a plan view of a substrate of a filter unit according to a seventh preferred embodiment of the present invention.

FIG. 15 is a diagram illustrating an example circuit configuration of a filter device according to an eighth preferred embodiment of the present invention.

FIG. 16 is a diagram illustrating an example circuit configuration of a filter device according to a ninth preferred embodiment of the present invention.

### DETAILED DESCRIPTION OF THE PREFERRED EMBODIMENTS

Preferred embodiments of the present invention will be described below with reference to the accompanying drawings. In the drawings, components denoted by the same reference numerals have the same or similar structure and functions.

### First Preferred Embodiment

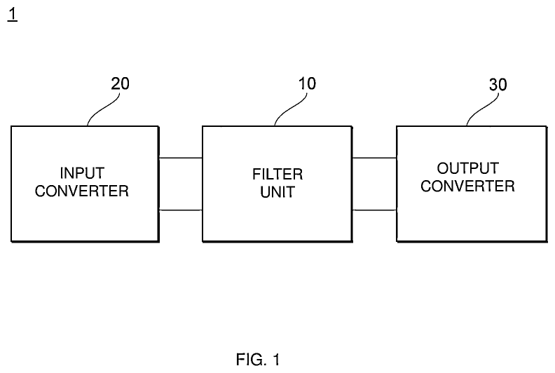

FIG. 1 is a diagram illustrating an example schematic configuration of a filter device 1 according to a first preferred embodiment of the present invention. As illustrated in FIG. 1, the filter device 1 according to the present preferred embodiment includes a filter unit 10, an input converter 20, and an output converter 30. The input converter 20 is connected to the input side of the filter unit 10, and the output converter 30 is connected to the output side of the filter unit 10.

If an unbalanced signal is input to the input converter 20, the input converter 20 can convert the input unbalanced signal into a balanced signal. In the present preferred embodiment, the input converter 20 inputs the resulting balanced signal to the filter unit 10.

The filter unit 10 includes two ladder filters and has a pass band in a predetermined frequency band. In the present preferred embodiment, the filter unit 10 can pass a signal in a predetermined frequency band, which is a balanced signal input from the input converter 20, and input the signal to the output converter 30.

When a balanced signal is input to the output converter 30 from the filter unit 10, the output converter 30 can convert the input balanced signal into an unbalanced signal and output the resulting unbalanced signal.

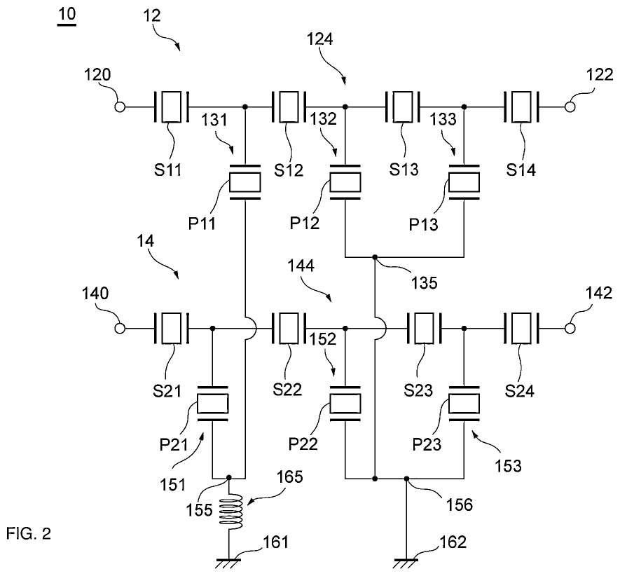

FIG. 2 is a diagram illustrating an example of a circuit configuration of the filter unit 10 according to the first preferred embodiment of the present invention. As illustrated in FIG. 2, the filter unit 10 according to the present preferred embodiment includes a first filter 12 and a second filter 14. Both of the first filter 12 and the second filter 14 are ladder filters.

The first filter 12 mainly includes a first input terminal 120, a first output terminal 122, a first series arm 124, and three first parallel arms 131, 132, and 133, and has a pass band in a predetermined frequency band.

The first series arm 124 connects the first input terminal 120 and the first output terminal 122. In the first series arm 124, four first series arm resonators S11, S12, S13, and S14 are arranged in order from closest to the first input terminal 120 to farthest from the first input terminal 120.

The three first parallel arms 131, 132, and 133 include first parallel arm resonators P11, P12, and P13, respectively. The three first parallel arms 131, 132, and 133 are connected to the first series arm 124. Specifically, one end of the first parallel arm 131 is connected to the first series arm 124 between the first series arm resonator S11 and the first series arm resonator S12. One end of the first parallel arm 132 is connected to the first series arm 124 between the first series arm resonator S12 and the first series arm resonator S13. One end of the first parallel arm 133 is connected to the first series arm 124 between the first series arm resonator S13 and the first series arm resonator S14. The first parallel arm 132 and the first parallel arm 133 are connected at a node 135.

The elements of the first series arm resonators S11, S12, S13, and S14 and the first parallel arm resonators P11, P12, and P13 are not particularly limited, and may be surface acoustic wave (SAW) resonators, thin-film piezoelectric resonators, bulk acoustic wave (BAW) resonators, or the like, for example. The same applies to various resonators described below (e.g., various resonators included in the second filter 14).

The second filter 14 mainly includes a second input terminal 140, a second output terminal 142, a second series arm 144, and three second parallel arms 151, 152, and 153, and has a pass band in a predetermined frequency band. The pass band of the second filter 14 is a pass band in the same or substantially the same frequency band as the pass band of the first filter 12.

The second filter 14 may have the same or substantially the same ladder filter configuration as the first filter 12. For example, the first filter 12 and the second filter 14 may include the same number of series arm resonators and the same number of parallel arms. Further, in the first filter 12 and the second filter 14, the corresponding parallel arms may be connected at the same or substantially the same positions in the respective series arms, and the corresponding resonators may have the same or substantially the same characteristics (e.g., the resonant frequency and the anti-resonant frequency).

The second series arm 144 connects the second input terminal 140 and the second output terminal 142. In the second series arm 144, four second series arm resonators S21, S22, S23, and S24 are arranged in order from closest to the second input terminal 140 to farthest from the second input terminal 140.

The three second parallel arms 151, 152, and 153 include second parallel arm resonators P21, P22, and P23, respectively. The three second parallel arms 151, 152, and 153 are connected to the second series arm 144. Specifically, one end of the second parallel arm 151 is connected to the second series arm 144 between the second series arm resonator S21 and the second series arm resonator S22. One end of the second parallel arm 152 is connected to the second series arm 144 between the second series arm resonator S22 and the second series arm resonator S23. One end of the second parallel arm 153 is connected to the second series arm 144 between the second series arm resonator S23 and the second series arm resonator S24.

The node 135 of the first filter 12 described above is electrically connected to the second parallel arm 152. The second parallel arm 152 and the second parallel arm 153 are connected at a node 156. The node 156 is further connected to a ground terminal 162.

The first parallel arm resonator P11 in the first parallel arm 131 and the second parallel arm resonator P21 in the second parallel arm 151 are electrically connected at a node 155. When a balanced signal is input to the first filter 12 and the second filter 14, the potential of the first parallel arm resonator P11 in the first series arm 124 may be equal or substantially equal to the potential of the second parallel arm resonator P21 in the second series arm 144.

The description of the present preferred embodiment is directed to an example in which the first series arm 124 and the second series arm 144 each include four series arm resonators. However, the number of series arm resonators in each of the first series arm 124 and the second series arm 144 may be three or less, or may be five or more.

Further, the description of the present preferred embodiment is directed to an example in which three parallel arms are connected to the first series arm 124 and the second series arm 144. However, the number of parallel arms connected to each of the first series arm 124 and the second series arm 144 may be two, or may be four or more. Further, the description of the present preferred embodiment is directed to an example in which the first parallel arms 131, 132, and 133 and the second parallel arms 151, 152, and 153 each include one parallel arm resonator. Alternatively, each parallel arm may include a plurality of parallel arm resonators.

In the present preferred embodiment, an inductor 165 is connected in series to the first parallel arm resonator P11 and the second parallel arm resonator P21. Specifically, the inductor 165 includes one end electrically connected to the node 155, and another end electrically connected to a ground terminal 161.

In the present preferred embodiment, the inductor 165 is connected to the first parallel arm resonator P11 and the second parallel arm resonator P21, which are closest to the first input terminal 120 and the second input terminal 140, respectively. Alternatively, an inductor may be connected to a first parallel arm resonator and a second parallel arm resonator that are connected to the series arms at positions that have the same or substantially the same potential when a balanced signal is input to the first filter 12 and the second filter 14. For example, an inductor may be connected to a first parallel arm resonator in a first parallel arm that is the N-th closest to the first input terminal 120 (where N is a natural number) and a second parallel arm resonator in a second parallel arm that is the N-th closest to the second input terminal 140.

In the present preferred embodiment, the filter unit 10 includes two ladder filters, and an input balanced signal is input to these filters. At this time, the signal is distributed to the two filters. Thus, the electric power handling capability of the filter device 1 is increased by about two times. Accordingly, the filter device 1 can be used to filter high-power differential signals output from a power amplifier having a differential configuration, for example.

The filter device 1 further includes an inductor connected between a ground terminal and a parallel arm resonator included in at least one parallel arm among the plurality of first and second parallel arms. This configuration can further widen the pass band of the filter device 1 while increasing the electric power handling capability as compared with the configuration in which a filter unit includes only resonators.

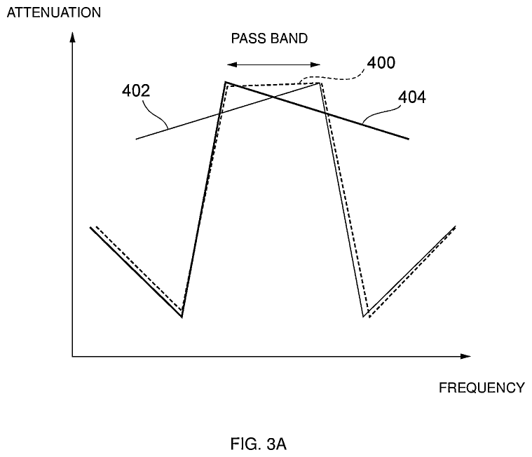

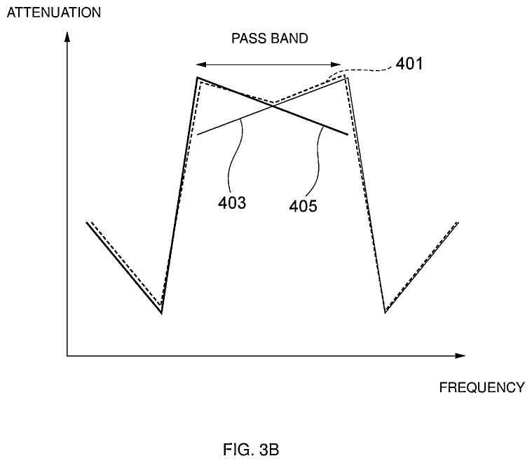

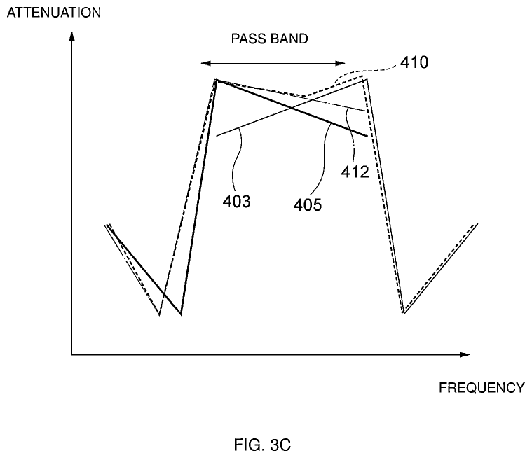

The combination of the wide pass band and high electric power handling capability of the filter device 1 according to the present preferred embodiment will be described with reference to FIGS. 3A to 3C. FIG. 3A is a diagram illustrating an example of a bandpass characteristic of a ladder filter. FIG. 3B is a diagram illustrating a bandpass characteristic of a ladder filter having a wider pass band than a pass band illustrated in FIG. 3A. FIG. 3C is a diagram illustrating a bandpass characteristic of a ladder filter having a parallel arm resonator to which an inductor is connected.

In FIG. 3A, a bandpass characteristic 400 of a ladder filter is indicated by a broken line, and a component 402 of a parallel arm resonator and a component 404 of a series arm resonator are indicated by solid lines. In a typical ladder filter, the difference between the anti-resonant frequency of a series arm resonator and the resonant frequency of a parallel arm resonator is increased to widen the pass band. In this case, the loss is increased in a frequency band away from the anti-resonant frequency of the series arm resonator or the resonant frequency of the parallel arm resonator.

In FIG. 3B, a bandpass characteristic 401 having a pass band that is wider than the pass band in FIG. 3A is indicated by a broken line, and a component 403 of a parallel arm resonator and a component 405 of a series arm resonator are indicated by solid lines. As illustrated in FIG. 3B, it was discovered that the bandpass characteristic deteriorates near the center of the pass band.

In a case where an inductor is connected to a parallel arm resonator, as in the present preferred embodiment, a component 412 of the parallel arm resonator is improved due to the inductive component of the inductor, as compared with a case where a filter unit includes only resonators. Accordingly, as illustrated in FIG. 3C, the loss near the center of a bandpass characteristic 410 is reduced, making it possible to pass the input balanced signal while reducing or preventing the degradation of the input balanced signal. As a result, the pass band of the filter device 1 can be widened with increased electric power handling capability.

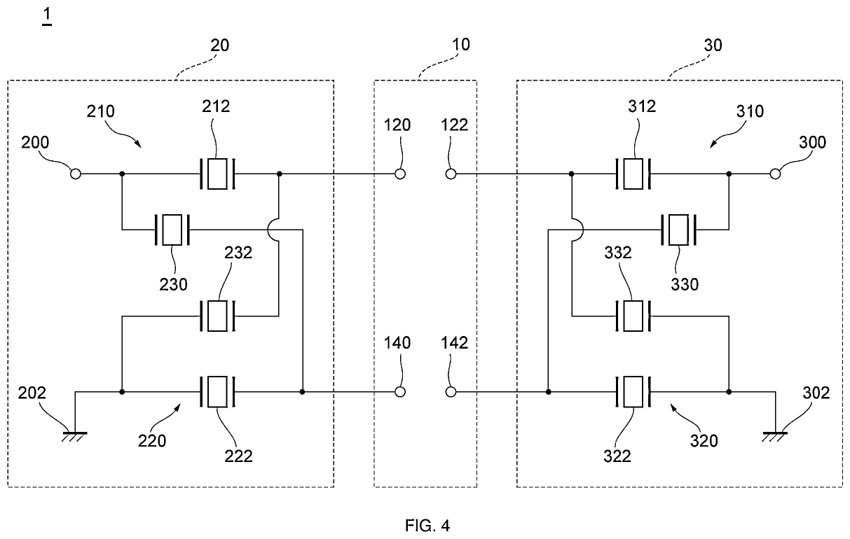

FIG. 4 is a diagram illustrating an example of a circuit configuration of the input converter 20 and the output converter 30 according to the present preferred embodiment. In FIG. 4, the configuration of the filter unit 10 is illustrated in a simplified manner, and the first input terminal 120, the first output terminal 122, the second input terminal 140, and the second output terminal 142 of the filter unit 10 are illustrated.

The input converter 20 according to the present preferred embodiment mainly includes an input terminal 200, a ground terminal 202, and four resonators 212, 222, 230, and 232. An unbalanced signal is input to the input converter 20. In the present preferred embodiment, an unbalanced signal is input between the input terminal 200 and the ground terminal 202. The input converter 20 converts the input unbalanced signal into a balanced signal and inputs the resulting balanced signal to the first input terminal 120 and the second input terminal 140.

The resonator 212 is disposed in a path 210 connecting the input terminal 200 and the first input terminal 120 of the first filter 12. The resonator 222 is disposed in a path 220 connecting the ground terminal 202 and the second input terminal 140 of the second filter 14. One end of the resonator 230 is connected to the path 210 between the input terminal 200 and the resonator 212, and the other end of the resonator 230 is connected to the path 220 between the resonator 222 and the second input terminal 140.

One end of the resonator 232 is connected to the path 210 between the resonator 212 and the first input terminal 120, and the other end of the resonator 232 is connected to the path 220 between the ground terminal 202 and the resonator 222.

The output converter 30 according to the present preferred embodiment mainly includes an output terminal 300, a ground terminal 302, and four resonators 312, 322, 330, and 332. A balanced signal is input to the output converter 30. In the present preferred embodiment, an output difference between the first output terminal 122 and the second output terminal 142 of the filter unit 10 is input to the output converter 30 as a balanced signal. The output converter 30 combines the input outputs of the first output terminal 122 and the second output terminal 142 to convert the balanced signal into an unbalanced signal. The resulting unbalanced signal is output from the output terminal 300 and the ground terminal 302.

The resonator 312 is disposed in a path 310 connecting the output terminal 300 and the first output terminal 122 of the filter unit 10. The resonator 322 is disposed in a path 320 connecting the ground terminal 302 and the second output terminal 142 of the filter unit 10. One end of the resonator 330 is connected to the path 310 between the resonator 312 and the output terminal 300, and the other end of the resonator 330 is connected to the path 320 between the second output terminal 142 and the resonator 322. One end of the resonator 332 is connected to the path 310 between the first output terminal 122 and the resonator 312, and the other end of the resonator 332 is connected to the path 320 between the resonator 322 and the ground terminal 302.

In the present preferred embodiment, the filter device 1 includes the output converter 30, which is configured using a plurality of resonators. Accordingly, the filter device 1 can convert the balanced signals output from the first filter 12 and the second filter 14 into unbalanced signals, and can reduce or prevent the generation of harmonic components.

The resonators 312, 322, 330, and 332 of the output converter 30 may have a higher coupling coefficient than any of the first series arm resonators S11, S12, S13, and S14, the first parallel arm resonators P11, P12, and P13, the second series arm resonators S21, S22, S23, and S24, and the second parallel arm resonators P21, P22, and P23. As a result, the band of the output converter 30 can be made wider, and the loss of the signals to be combined in the output converter 30 is reduced.

The description of the present preferred embodiment is directed to an example in which the input converter 20 and the output converter 30 are configured using various resonators. However, the input converter 20 and the output converter 30 may be configured using an inductor, a capacitor, or the like, instead of the resonators.

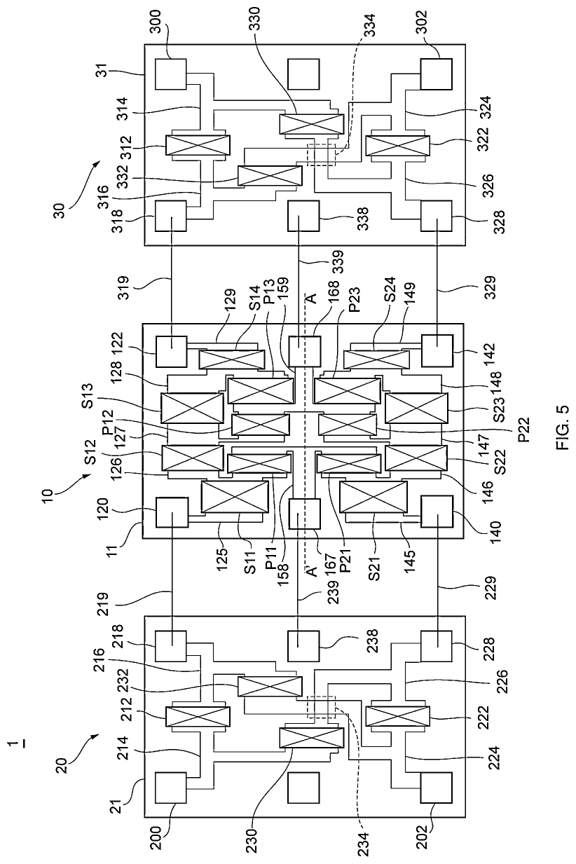

FIG. 5 is a diagram illustrating an example of a layout of the filter unit 10, the input converter 20, and the output converter 30 of the filter device 1 according to the present preferred embodiment. In the present preferred embodiment, the filter unit 10, the input converter 20, and the output converter 30 each include a substrate made of various piezoelectric materials, and various resonators, various lines, and so on provided on the substrate. FIG. 5 is a plan view of the respective substrates. In the example illustrated in FIG. 5, the various resonators of the filter unit 10 are SAW resonators.

The filter unit 10 and the input converter 20 are electrically connected by three line bars 219, 229, and 239. The filter unit 10 and the output converter 30 are electrically connected by three line bars 319, 329, and 339.

The filter unit 10 includes a substrate 11, and various resonators, various lines, and so on provided on the substrate 11. Further, an upper portion of the filter unit 10 with respect to the broken line A-A′ illustrated in FIG. 5 mainly includes a first filter, and a lower portion of the filter unit 10 with respect to the broken line A-A′ mainly includes a second filter. In the present preferred embodiment, the first filter and the second filter are symmetrical or substantially symmetrical to each other when the substrate 11 is viewed in plan view. Specifically, the first filter and the second filter are symmetric or substantially symmetrical with respect to the broken line A-A′.

Further, the various design values (e.g., the lengths of the lines, the film thicknesses of electrodes, the positional relationship between the various resonators, and the like) of the corresponding configurations of the first filter and the second filter may be the same or substantially the same. Accordingly, the frequency characteristic of the first filter and the frequency characteristic of the second filter are closer to one another. As a result, the outputs of the first filter and the second filter are more equivalent (the same or substantially the same amplitude and the same or substantially the same phase). The loss of the signals to be combined by the output converter 30 is reduced, and the attenuation characteristics are improved.

The first filter and the second filter may be asymmetrical to each other when the substrate is viewed in plan view. For example, the signal input to the first filter and the signal input to the second filter are out of balance in some cases. In such cases, the balance between the signals can be corrected with the first filter and the second filter that are positioned asymmetrically. For example, the lengths of the lines of the first filter or the second filter may be adjusted, or the positional relationship between the plurality of resonators of the first filter or the second filter may be adjusted. As a result, the outputs of the first filter and the second filter can be efficiently combined by the output converter 30, and the signal loss can be reduced.

An upper portion of the substrate 11 with respect to the broken line A-A′ includes, for example, the components of the first filter, such as the first input terminal 120, the first output terminal 122, the first series arm resonators S11, S12, S13, and S14, and the first parallel arm resonators P11, P12, and P13.

The first input terminal 120 is electrically connected to the first series arm resonator S11 via a line 125. The first series arm resonator S11 is electrically connected to the first series arm resonator S12 and the first parallel arm resonator P11 via a line 126. The first series arm resonator S12 is electrically connected to the first series arm resonator S13 and the first parallel arm resonator P12 via a line 127. The first series arm resonator S13 is electrically connected to the first series arm resonator S14 and the first parallel arm resonator P13 via a line 128. The first series arm resonator S14 is electrically connected to the first output terminal 122 via a line 129.

A lower portion of the substrate 11 with respect to the broken line A-A′ includes, for example, the components of the second filter, such as the second input terminal 140, the second output terminal 142, the second series arm resonators S21, S22, S23, and S24, and the second parallel arm resonators P21, P22, and P23.

The second input terminal 140 is electrically connected to the second series arm resonator S21 via a line 145. The second series arm resonator S21 is electrically connected to the second series arm resonator S22 and the second parallel arm resonator P21 via a line 146. The second series arm resonator S22 is electrically connected to the second series arm resonator S23 and the second parallel arm resonator P22 via a line 147. The second series arm resonator S23 is electrically connected to the second series arm resonator S24 and the second parallel arm resonator P23 via a line 148. The second series arm resonator S24 is electrically connected to the second output terminal 142 via a line 149.

The substrate 11 also includes an electrode 167 and an electrode 168 along the broken line A-A′. The electrode 167 is electrically connected to the first parallel arm resonator P11 and the second parallel arm resonator P21 via a line 158. The electrode 168 is electrically connected to the first parallel arm resonators P12 and P13 and the second parallel arm resonators P22 and P23 via a line 159.

In the present preferred embodiment, a balanced signal is input to the first filter and the second filter, and signals in the respective pass bands are mainly input to the output converter 30, where the signals input from the first filter and the second filter are combined. At this time, it is preferable that each of the first filter and the second filter has a short path (e.g., a short line length) because the balance of the respective signals is maintained and the loss of the signals to be combined is reduced. In addition, since the loss is reduced, heat generation due to the loss is reduced or prevented, resulting in a further increase in the electric power handling capability of the filter device 1.

The input converter 20 includes a substrate 21, and various resonators, various lines, and so on provided on the substrate 21. The substrate 21 includes, for example, the input terminal 200, the ground terminal 202, the resonators 212, 222, 230, and 232, and so on.

The input terminal 200 is electrically connected to the resonators 212 and 230 via a line 214. The resonator 212 is electrically connected to the resonator 232 and an electrode 218 via a line 216. The electrode 218 is electrically connected to the first input terminal 120 of the substrate 11 via the line bar 219.

The ground terminal 202 is electrically connected to the resonators 222 and 232 via a line 224. The resonator 222 is electrically connected to the resonator 230 and an electrode 228 via a line 226. In a region 234 surrounded by a dashed line, the line 224 and the line 226 overlap each other in a direction perpendicular or substantially perpendicular to the plane of the drawing. The electrode 228 is electrically connected to the second input terminal 140 of the substrate 11 via the line bar 229. An electrode 238 is electrically connected to the electrode 167 of the substrate 11 via the line bar 239.

The output converter 30 includes a substrate 31, and various resonators, various lines, and so on provided on the substrate 31. The substrate 31 includes, for example, the output terminal 300, the ground terminal 302, the resonators 312, 322, 330, and 332, and so on.

The output terminal 300 is electrically connected to the resonators 312 and 330 via a line 314. The resonator 312 is electrically connected to the resonator 332 and an electrode 318 via a line 316. The electrode 318 is electrically connected to the first output terminal 122 of the substrate 11 via the line bar 319.

The ground terminal 302 is electrically connected to the resonators 322 and 332 via a line 324. The resonator 322 is electrically connected to the resonator 330 and an electrode 328 via a line 326. In a region 334 surrounded by a dashed line, the line 324 and the line 326 overlap each other in a direction perpendicular or substantially perpendicular to the plane of the drawing. The electrode 328 is electrically connected to the second output terminal 142 of the substrate 11 via the line bar 329. An electrode 338 is electrically connected to the electrode 168 of the substrate 11 via the line bar 339.

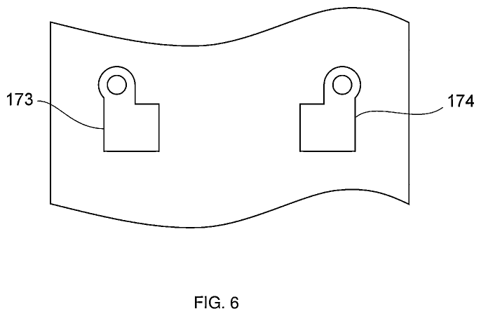

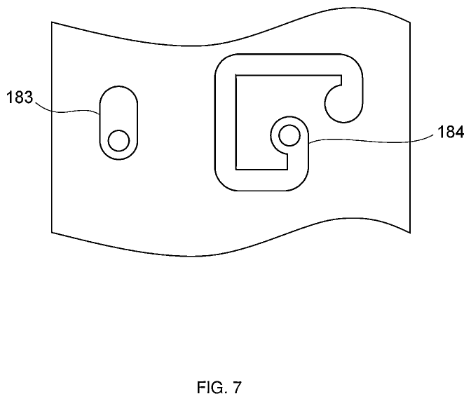

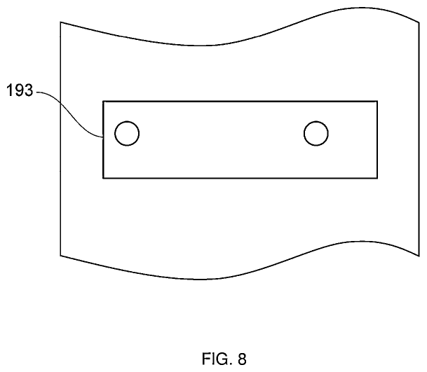

In the present preferred embodiment, the filter unit 10 has a multilayer structure. The substrate 11 illustrated in FIG. 5 may be connected to the multilayer structure via a bump, for example. The multilayer structure of the filter unit 10 will be described with reference to FIGS. 6 to 8. FIG. 6 is a schematic view of a first layer of the filter unit 10, FIG. 7 is a schematic view of a second layer of the filter unit 10, and FIG. 8 is a schematic view of a third layer of the filter unit 10.

The electrode 167 of the substrate 11 illustrated in FIG. 5 is electrically connected to an electrode 173 in the first layer illustrated in FIG. 6 via a bump (not illustrated). The electrode 173 is electrically connected to an electrode 193 illustrated in FIG. 8 via an electrode 183 illustrated in FIG. 7. The electrode 193 is grounded. In the present preferred embodiment, all of the various grounded parallel arm resonators of the filter unit 10 are grounded via the electrode 193.

The electrode 168 of the substrate 11 illustrated in FIG. 5 is electrically connected to an electrode 174 in the first layer illustrated in FIG. 6 via a bump (not illustrated). The electrode 174 is electrically connected to the electrode 193 illustrated in FIG. 8 via an electrode 184 illustrated in FIG. 7. The electrode 184 illustrated in FIG. 7 mainly includes the inductor 165 illustrated in FIG. 2.

The filter device 1 according to the present preferred embodiment includes the first filter 12 including the first input terminal 120, the first output terminal 122, the first series arm 124 connecting the first input terminal 120 and the first output terminal 122 and including the plurality of first series arm resonators S11, S12, S13, and S14, and the plurality of first parallel arms 131, 132, and 133 connected to the first series arm 124 and including the first parallel arm resonators P11, P12, P13, and P14, respectively, the first filter 12 having a pass band in a predetermined frequency band, a second filter 14 including the second input terminal 140, the second output terminal 142, the second series arm 144 connecting the second input terminal 140 and the second output terminal 142 and including the plurality of second series arm resonators S21, S22, S23, and S24, and the plurality of second parallel arms 151, 152, and 153 connected to the second series arm 144 and including the second parallel arm resonators P21, P22, and P23, respectively, the second filter 14 having a pass band in the predetermined frequency band, the substrate 11 including the first filter 12 and the second filter 14, and the inductor 165 connected between the ground terminal 161 and the parallel arm resonators P11 and P21 included in at least one parallel arm among the plurality of first parallel arms 131, 132, and 133 and the plurality of second parallel arms 151, 152, and 153.

According to the present preferred embodiment, the filter device 1 includes two filters. Thus, an input signal is distributed to the two filters. As a result, the load on the filters is reduced as compared with a case where a signal is input to one filter, and the electric power handling capability is increased. In addition, as described above with reference to FIGS. 3A to 3C, the pass band can be further widened.

Further, a first parallel arm resonator in a first parallel arm that is the N-th closest to the first input terminal 120 and a second parallel arm resonator in a second parallel arm that is the N-th closest to the second input terminal 140 may be electrically connected at a node, and the inductor 165 may be electrically connected to the node.

According to the present preferred embodiment, the frequency characteristics of the first filter 12 and the second filter 14 can be made more homogeneous, and the signal loss can be reduced. As a result, the electric power handling capability can be further increased.

The first series arm resonators S11, S12, S13, and S14, the first parallel arm resonators P11, P12, and P13, the second series arm resonators S21, S22, S23, and S24, and the second parallel arm resonators P21, P22, and P23 may each be at least one of a SAW resonator or a BAW resonator, for example.

According to the present preferred embodiment, the filter device 1 can be provided with a simple configuration.

The filter device 1 may further include the output converter 30 that receives an output difference between the first output terminal 122 and the second output terminal 142 and converts the received output difference into an unbalanced signal.

According to the present preferred embodiment, the balanced signals input from the first filter 12 and the second filter 14 can be converted into an unbalanced signal, and the resulting unbalanced signal can be output.

The filter device 1 may further include the input converter 20 that receives an unbalanced signal, converts the received unbalanced signal into a balanced signal, and inputs the balanced signal to the first input terminal 120 and the second input terminal 140.

According to the present preferred embodiment, a balanced signal is input to the first filter 12 and the second filter 14. At this time, the input signal is small as compared with a case where an unbalanced signal is input to each filter. Thus, the load on each filter is reduced. As a result, the electric power handling capability of the filter device 1 is further increased.

### Second Preferred Embodiment

The description of a second preferred embodiment of the present invention is mainly directed to differences from the first preferred embodiment, and the description of the same or substantially the same elements as those of the first preferred embodiment will be appropriately omitted. In the second preferred embodiment, the various components described in the first preferred embodiment are applicable.

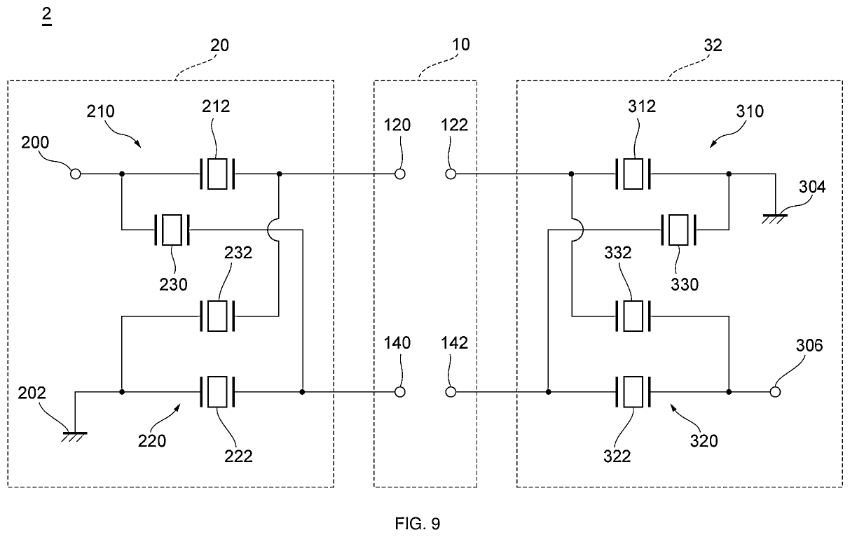

FIG. 9 is a diagram illustrating a circuit configuration of a filter device 2 according to the second preferred embodiment. In the filter device 2 according to the second preferred embodiment, in an output converter 32, the path 310 connected to the first output terminal 122 is connected to a ground terminal 304, instead of an output terminal. In the output converter 32, furthermore, the path 320 connected to the second output terminal 142 is connected to an output terminal 306, instead of a ground terminal.

In the present preferred embodiment, the upper paths 210 and 310 and the lower paths 220 and 320 are connected to a ground terminal and an input or output terminal. Accordingly, the balance of the signals in the upper paths 210 and 310 and the lower paths 220 and 320 is corrected. As a result, the signal loss is reduced, and the electric power handling capability of the filter device 2 is further increased.

### Third Preferred Embodiment

The description of a third preferred embodiment of the present invention is directed to another configuration of a filter unit, and the description of the same or substantially the same elements as those of the preferred embodiments described above will be appropriately omitted. In the third preferred embodiment, the various components described in the preferred embodiments described above are applicable.

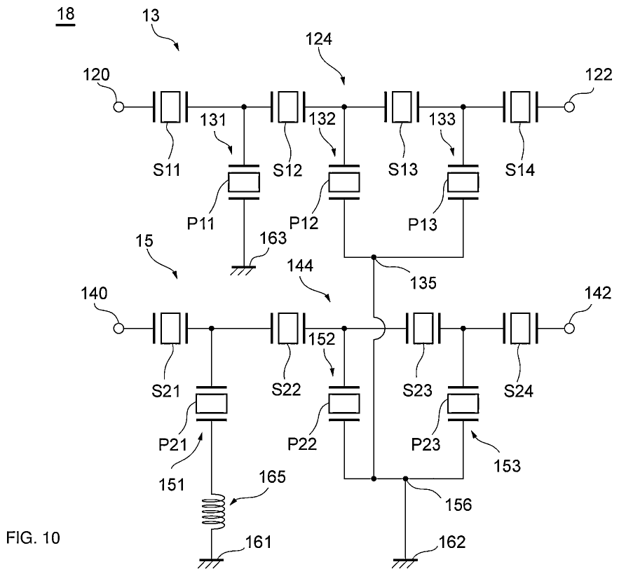

FIG. 10 is a diagram illustrating a circuit configuration of a filter unit 18 according to the third preferred embodiment. In a first filter 13 according to the third preferred embodiment, the first parallel arm 131, which is closest to the first input terminal 120, is not connected to a parallel arm of a second filter 15, but is connected to a ground terminal 163.

In the second filter 15 according to the third preferred embodiment, the second parallel arm 151, which is closest to the second input terminal 140, is not connected to a parallel arm of the first filter 13, but is connected to the ground terminal 161 via the inductor 165.

The pass band of the filter device 2 according to the present preferred embodiment can also be widened with increased electric power handling capability.

### Fourth Preferred Embodiment

The description of a fourth preferred embodiment of the present invention is directed to another configuration of an output converter, and the description of the same or substantially the same elements as those of the preferred embodiments described above will be appropriately omitted. In the fourth preferred embodiment, the various components described in the preferred embodiments described above are applicable.

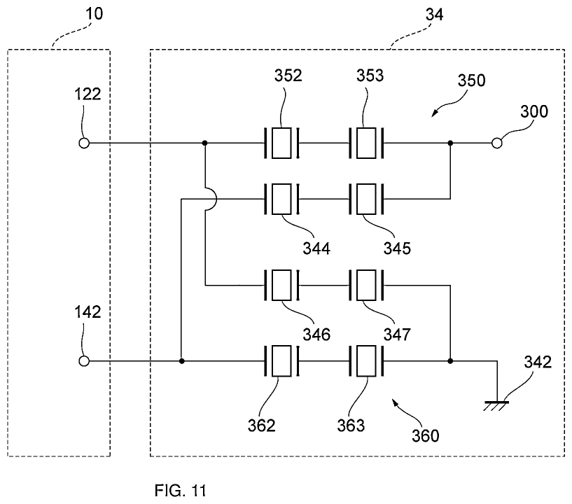

FIG. 11 is a diagram illustrating a circuit configuration of an output converter 34 according to the fourth preferred embodiment. In FIG. 11, the filter unit 10 is illustrated in a simplified way, in which only the first output terminal 122 and the second output terminal 142 are illustrated. The output converter 34 according to the present preferred embodiment includes a plurality of adjacent resonators connected in series. For example, two resonators 352 and 353 connected in series are disposed adjacent to one another in a path 350 connecting the first output terminal 122 and an output terminal 340. Further, two resonators 362 and 363 connected in series are disposed adjacent to each other in a path 360 connecting the second output terminal 142 and a ground terminal 342.

Further, two resonators 346 and 347 connected in series are disposed adjacent to each other in a path connecting the path 350 between the first output terminal 122 and the resonator 352 and the path 360 between the resonator 363 and the ground terminal 342. Further, two resonators 344 and 345 connected in series are disposed adjacent to each other in a path connecting the path 350 between the resonator 353 and the output terminal 340 and the path 360 between the second output terminal 142 and the resonator 362.

In the present preferred embodiment, the output converter 34 includes a plurality of adjacent resonators connected in series, thus further widening the band of the output converter 34 and reducing the loss of the signals to be combined in the output converter 34.

### Fifth Preferred Embodiment

The description of a fifth preferred embodiment of the present invention is directed to another configuration of an output converter, and the description of the same or substantially the same elements as those of the preferred embodiments described above will be appropriately omitted. In the fifth preferred embodiment, the various components described in the preferred embodiments described above are applicable.

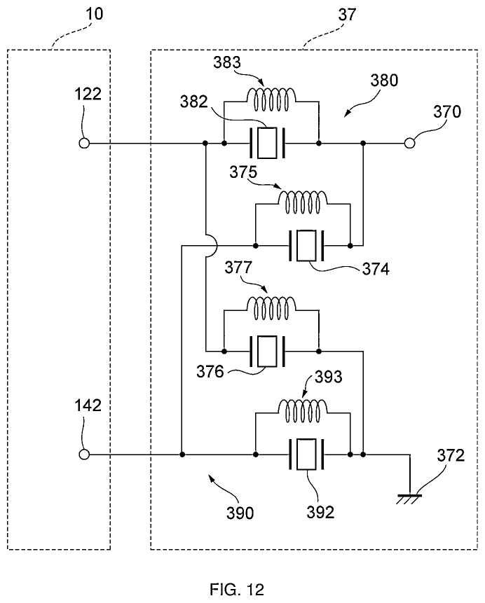

FIG. 12 is a diagram illustrating a circuit configuration of an output converter 37 according to the fifth preferred embodiment. In FIG. 12, the filter unit 10 is illustrated in a simplified way, in which only the first output terminal 122 and the second output terminal 142 are illustrated. In the fifth preferred embodiment, the output converter 37 further includes an inductor connected in parallel to at least one of the plurality of resonators. Specifically, an inductor is connected in parallel to each of four resonators included in the output converter 37.

For example, an inductor 383 is connected in parallel to a resonator 382 disposed in a path 380 connecting an output terminal 370 and the first output terminal 122 of the filter unit 10. Further, an inductor 393 is connected in parallel to a resonator 392 disposed in a path 390 connecting a ground terminal 372 and the second output terminal 142 of the filter unit 10. Further, an inductor 377 is connected in parallel to a resonator 376 connected to the path 380 between the first output terminal 122 and the resonator 382 and the path 390 between the resonator 392 and the ground terminal 372. Further, an inductor 375 is connected in parallel to a resonator 374 connected to the path 380 between the resonator 382 and the output terminal 370 and the path 390 between the second output terminal 142 and the resonator 392.

In the present preferred embodiment, the output converter 37 further includes an inductor connected in parallel to at least one of the plurality of resonators, thus further widening the band of the output converter 37 and reducing the loss of the signals to be combined in the output converter 37.

### Sixth Preferred Embodiment

The description of a sixth preferred embodiment of the present invention is directed to another configuration for the layout of a filter device, and the description of the same or substantially the same elements as those of the preferred embodiments described above will be appropriately omitted. In the sixth preferred embodiment, the various components described in the preferred embodiments described above are applicable.

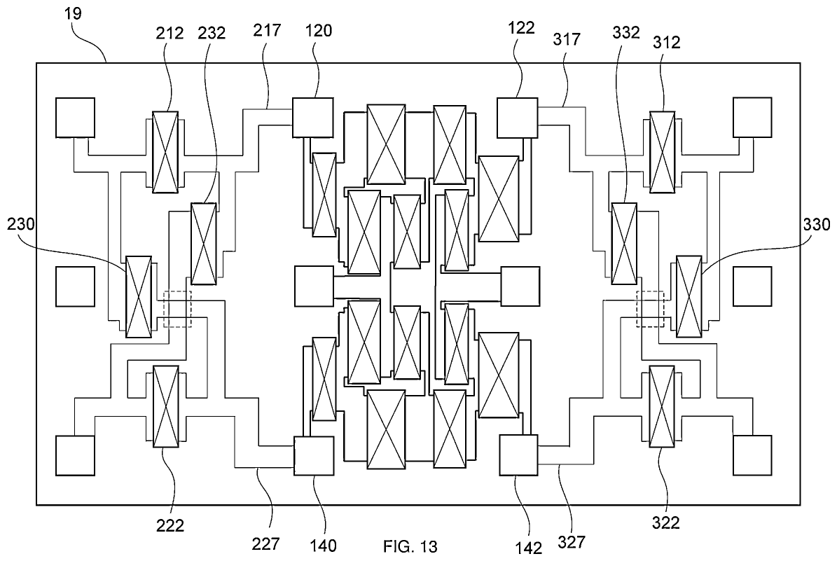

FIG. 13 is a view illustrating a layout of a filter device according to the sixth preferred embodiment. In the sixth preferred embodiment, unlike the first preferred embodiment described with reference to FIG. 5, an input converter, a filter unit, and an output converter are provided on one substrate 19.

In the sixth preferred embodiment, the electrodes 218, 228, and 238 on the substrate 21 illustrated in FIG. 5 are omitted, and the first input terminal 120 and the second input terminal 140 of the filter unit 10 are shared by the input converter and the filter unit. For example, the first input terminal 120 is electrically connected to the resonators 212 and 232 via a line 217. The second input terminal 140 is electrically connected to the resonators 222 and 230 via a line 227.

In the sixth preferred embodiment, furthermore, the electrodes 318, 328, and 338 on the substrate 31 illustrated in FIG. 5 are omitted, and the first output terminal 122 and the second output terminal 142 of the filter unit 10 are shared by the filter unit and the output converter. For example, the first output terminal 122 is electrically connected to the resonators 312 and 332 via a line 317. The second output terminal 142 is electrically connected to the resonators 322 and 330 via a line 327.

In the present preferred embodiment, providing the input converter, the filter unit, and the output converter on a single substrate can further reduce the size of the filter device. The foregoing description of the present preferred embodiment is directed to an example in which the input converter, the filter unit, and the output converter are provided on a single substrate. However, either the input converter or the output converter may be provided on another substrate.

### Seventh Preferred Embodiment

The description of a seventh preferred embodiment of the present invention is directed to a layout in which resonators included in a filter unit are BAW resonators. In the seventh preferred embodiment, the various components described in the preferred embodiments described above are applicable.

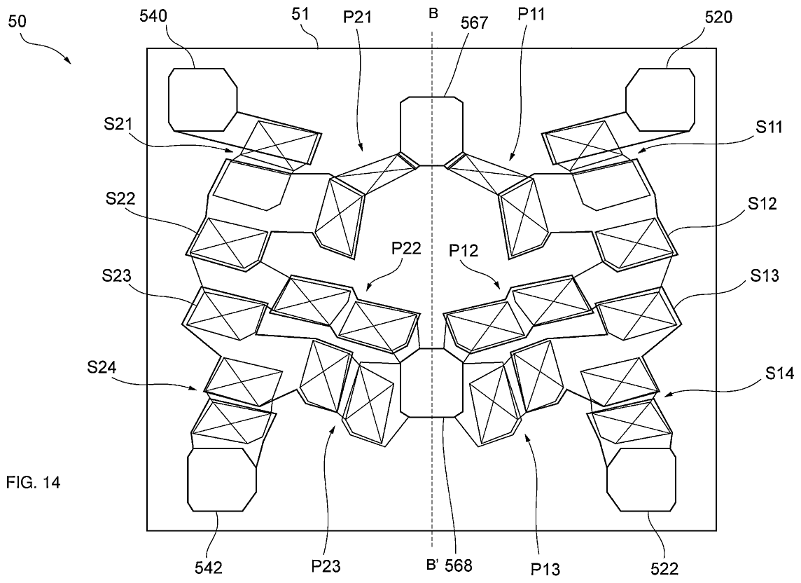

FIG. 14 is a plan view of a substrate 51 of a filter unit 50 according to the seventh preferred embodiment. As illustrated in FIG. 14, the filter unit 50 according to the seventh preferred embodiment includes the substrate 51, which is made of a piezoelectric material, and various BAW resonators, various lines, and so on provided on the substrate 51. A right portion of the filter unit 50 with respect to the broken line B-B′ illustrated in FIG. 14 mainly defines a first filter, and a left portion of the filter unit 50 with respect to the broken line B-B′ mainly defines a second filter. The first filter and the second filter are symmetric or substantially symmetric with respect to the broken line B-B′.

The first filter according to the present preferred embodiment includes a first input terminal 520, a first output terminal 522, four first series arm resonators S11, S12, S13, and S14, and three first parallel arm resonators P11, P12, and P13. These terminals and resonators are connected via lines to utilize the same or substantially the same circuit configuration as that of the first filter 12 illustrated in FIG. 2.

The second filter according to the present preferred embodiment includes a second input terminal 540, a second output terminal 542, four second series arm resonators S21, S22, S23, and S24, and three second parallel arm resonators P21, P22, and P23. These terminals and resonators are connected via lines to utilize the same or substantially the same circuit configuration as that of the second filter 14 illustrated in FIG. 2.

The substrate 51 has an electrode 567 and an electrode 568. These electrodes correspond to the electrode 167 and the electrode 568 illustrated in FIG. 5, respectively. That is, the electrode 567 is electrically connected to an inductor, and the electrode 168 is electrically connected to a ground terminal.

### Eighth Preferred Embodiment

The description of an eighth preferred embodiment of the present invention is directed to a filter device that filters a transmission signal output from a power amplifier and also filters a reception signal input to the filter device from the outside.

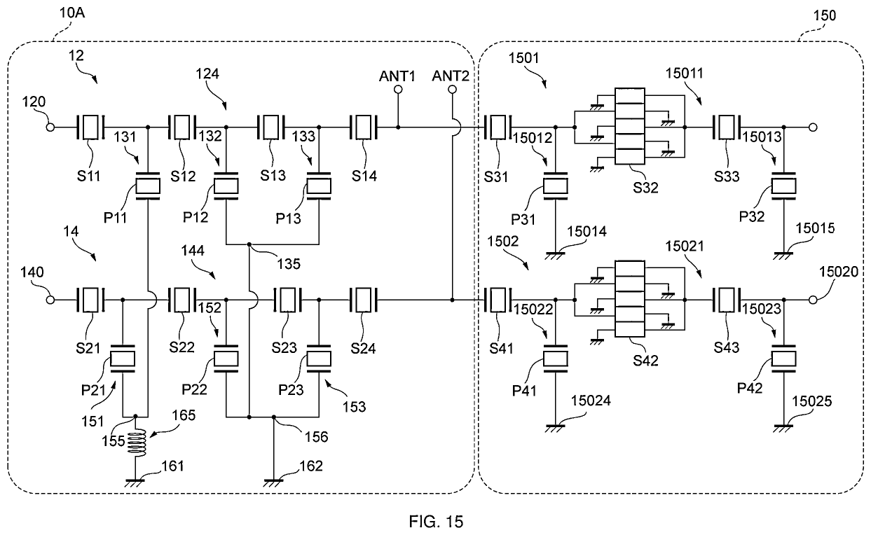

FIG. 15 is a diagram illustrating a circuit configuration of a filter unit 10A and a filter unit 150 of a filter device according to the eighth preferred embodiment.

The filter unit 10A has a configuration in which the first output terminal 122 and the second output terminal 142 in the configuration of the filter unit 10 described in the first preferred embodiment are replaced by an antenna terminal ANT1 (first antenna terminal) and an antenna terminal ANT2 (second antenna terminal), respectively. The differential signals input to the filter unit 10A are output from the antenna terminals ANT1 and ANT2 and are finally combined by a circuit subsequent to the antenna terminals ANT1 and ANT2, and a resulting signal is output to the outside. In the filter unit 10A, the first filter 12 defines and functions as a first transmission filter, and the second filter 14 defines and functions as a second transmission filter. In the filter unit 10A, furthermore, the first input terminal 120 defines and functions as a first transmission input terminal, and the second input terminal 140 defines and functions as a second transmission input terminal.

The filter unit 150 includes a first reception filter 1501 and a second reception filter 1502. The first reception filter 1501 is connected to the antenna terminal ANT1. The first reception filter 1501 filters a reception signal from the antenna terminal ANT1 and outputs the filtered signal from a first reception output terminal 15010. The second reception filter 1502 is connected to the antenna terminal ANT2. The second reception filter 1502 filters a reception signal from the antenna terminal ANT2 and outputs the filtered signal from a second reception output terminal 15020.

The signals to be input to the filter unit 150 are signals obtained by converting a signal input to an antenna (not illustrated) into differential signals. One of the differential signals is input to the first reception filter 1501 through the antenna terminal ANT1, and the other signal is input to the second reception filter 1502 through the antenna terminal ANT2.

The first reception filter 1501 mainly includes the first reception output terminal 15010, a third series arm 15011, and two third parallel arms 15012 and 15013. The first reception filter 1501 has a pass band in a predetermined frequency band (second frequency band) different from the pass band in the predetermined frequency band (first frequency band) of the first filter 12.

The third series arm 15011 connects the antenna terminal ANT1 and the first reception output terminal 15010. The third series arm 15011 includes a third series arm resonator S31, a first longitudinally coupled resonator S32, and a third series arm resonator S33 in this order from closest to the antenna terminal ANT1 to farthest from the antenna terminal ANT1.

The two third parallel arms 15012 and 15013 include third parallel arm resonators P31 and P32, respectively. The two third parallel arms 15012 and 15013 are connected to the third series arm 15011. Specifically, one end of the third parallel arm 15012 is connected to the third series arm 15011 between the third series arm resonator S31 and the first longitudinally coupled resonator S32, and the other end of the third parallel arm 15012 is connected to a ground terminal 15014. One end of the third parallel arm 15013 is connected to the third series arm 15011 between the third series arm resonator S33 and the first reception output terminal 15010, and the other end of the third parallel arm 15013 is connected to a ground terminal 15015.

The elements of the third series arm resonators S31 and S33 and the third parallel arm resonators P31 and P32 are not particularly limited, and may be surface acoustic wave resonators, thin-film piezoelectric resonators, bulk acoustic wave resonators, or the like, for example. The first longitudinally coupled resonator S32 is, for example, a surface acoustic wave resonator. The same applies to various resonators described below (e.g., various resonators included in the second reception filter 1502).

The second reception filter 1502 mainly includes the second reception output terminal 15020, a fourth series arm 15021, and two fourth parallel arms 15022 and 15023. The second reception filter 1502 has a pass band in a predetermined frequency band (second frequency band) different from the pass band in the predetermined frequency band (first frequency band) of the second filter 14. The pass band of the second reception filter 1502 is a pass band in the same or substantially the same frequency band as the pass band of the first reception filter 1501.

The second reception filter 1502 has a configuration the same as or similar to that of the first reception filter 1501. The fourth series arm 15021 of the second reception filter 1502 connects the antenna terminal ANT2 and the second reception output terminal 15020. Similar to the third series arm 15011, the fourth series arm 15021 includes a fourth series arm resonator S41, a second longitudinally coupled resonator S42, and a fourth series arm resonator S43. Like the third parallel arms 15012 and 15013, the fourth parallel arm 15022 including the fourth parallel arm resonator P41 and the fourth parallel arm 15023 including the fourth parallel arm resonator P42 are disposed between the fourth series arm 15021 and ground terminals 15024 and 15025, respectively.

The description of the present preferred embodiment is directed to an example in which the third series arm 15011 and the fourth series arm 15021 each include two series arm resonators and one longitudinally coupled resonator. However, the number of series arm resonators in each of the third series arm 15011 and the fourth series arm 15021 may be three or less, or may be five or more. In addition, the number of longitudinally coupled resonators may also be two or more. Further, the description of the present preferred embodiment is directed to an example in which the third parallel arms 15012 and 15013 and the fourth parallel arms 15022 and 15023 each include one parallel arm resonator. Alternatively, each parallel arm may include a plurality of parallel arm resonators. Furthermore, preferably, the reception filters 1501 and 1502 each include either a series arm resonator or a parallel arm resonator in addition to a longitudinally coupled resonator. In other words, the third series arm 15011 and the fourth series arm 15021 may include a longitudinally coupled resonator and one or more series arm resonators, and may include no parallel arm. Alternatively, the third series arm 15011 and the fourth series arm 15021 may include a longitudinally coupled resonator alone, and may include only one parallel arm.

The first reception filter 1501 and the second reception filter 1502 may include the same number of series arm resonators and the same number of parallel arms. Further, in the first reception filter 1501 and the second reception filter 1502, the corresponding parallel arms may be connected at the same or substantially the same positions in the respective series arms, and the corresponding resonators may have the same or substantially the same characteristics (e.g., the resonant frequency and the anti-resonant frequency).

The first filter 12 and the second filter 14 may be provided on one substrate, and the first reception filter 1501 and the second reception filter 1502 may be provided on another substrate. Alternatively, the first filter 12, the second filter 14, the first reception filter 1501, and the second reception filter 1502 may be provided on a single substrate.

In the filter device according to the eighth preferred embodiment, for example, high-power differential signals output from a power amplifier having a differential configuration are distributed to the first filter 12 and the second filter 14, and are filtered and output. Thus, the electric power handling capability of the filter device with respect to a transmission signal is increased by about two times. In the filter device according to the eighth preferred embodiment, furthermore, reception signals input from the antenna terminals ANT1 and ANT2 having a differential configuration are distributed to the first reception filter 1501 and the second reception filter 1502 and are filtered. The filtered signals are output from the first reception output terminal 15010 and the second reception output terminal 15020. Thus, the electric power handling capability of the filter device with respect to a reception signal is increased by about two times.

### Ninth Preferred Embodiment

The description of a ninth preferred embodiment of the present invention is directed to a filter device that filters a transmission signal and also filters a reception signal, like the eighth preferred embodiment.

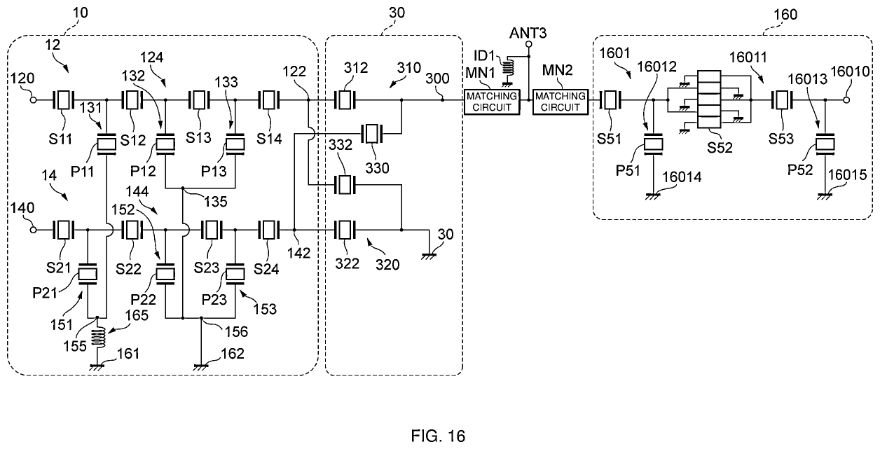

FIG. 16 is a diagram illustrating a circuit configuration of a filter unit 10, an output converter 30, and a filter unit 160 of a filter device according to the ninth preferred embodiment. The filter device according to the ninth preferred embodiment is different from the filter device according to the eighth preferred embodiment in that the filter unit 10 is connected to the output converter 30 via the first output terminal 122 and the second output terminal 142. The output converter 30 is connected to an antenna terminal ANT3 through a matching circuit MN1 connected to the output terminal 300. The differential signals input to the filter unit 10 are combined by the output converter 30, and a resulting signal is output from the antenna terminal ANT3. In the filter device, a choke inductor ID1 is disposed between the antenna terminal ANT3 and the ground.

The filter unit 160 includes a reception filter 1601. The reception filter 1601 is connected to the antenna terminal ANT3 through a matching circuit MN2. The reception filter 1601 filters a reception signal from the antenna terminal ANT3 and outputs the filtered signal from a reception output terminal 16010.

The reception filter 1601 mainly includes the reception output terminal 16010, a third series arm 16011, and two third parallel arms 16012 and 16013. The reception filter 1601 has a pass band in a predetermined frequency band (second frequency band) different from the pass bands in the predetermined frequency band (first frequency band) of the first filter 12 and the second filter 14.

The third series arm 16011 connects the antenna terminal ANT3 and the reception output terminal 16010. The third series arm 16011 includes a third series arm resonator S51, a longitudinally coupled resonator S52, and a third series arm resonator S53 in this order from closest to the antenna terminal ANT3 to farthest from the antenna terminal ANT3. The two third parallel arms 16012 and 16013 include third parallel arm resonators P51 and P52, respectively. The two third parallel arms 16012 and 16013 are connected to the third series arm 16011. Specifically, one end of the third parallel arm 16012 is connected to the third series arm 16011 between the third series arm resonator S51 and the longitudinally coupled resonator S52, and the other end of the third parallel arm 16012 is connected to a ground terminal 16014. One end of the third parallel arm 16013 is connected to the third series arm 16011 between the third series arm resonator S53 and the reception output terminal 16010, and the other end of the third parallel arm 16013 is connected to a ground terminal 16015.

The elements of the third series arm resonators S51 and S53 and the third parallel arm resonators P51 and P52 are not particularly limited, and may be surface acoustic wave resonators, thin-film piezoelectric resonators, bulk acoustic wave resonators, or the like, for example. The longitudinally coupled resonator S52 is, for example, a surface acoustic wave resonator.

The description of the present preferred embodiment is directed to an example in which the third series arm 16011 includes two series arm resonators and one longitudinally coupled resonator. However, the number of series arm resonators in the third series arm 16011 may be three or less, or may be five or more. In addition, the number of longitudinally coupled resonators may also be two or more. Further, the description of the present preferred embodiment is directed to an example in which the third parallel arms 16012 and 16013 each include one parallel arm resonator. Alternatively, each parallel arm may include a plurality of parallel arm resonators. Furthermore, preferably, the reception filter 1601 includes a third series arm resonator or a third parallel arm resonator in addition to the longitudinally coupled resonator S52. In other words, the third series arm 16011 may include the longitudinally coupled resonator S52 and one or more third series arm resonators, and may include no third parallel arm. Alternatively, the third series arm 16011 may include only the longitudinally coupled resonator S52 alone, and may include only either the third parallel arm 16012 or 16013.

The reception filter 1601 may include the same number of series arm resonators and the same number of parallel arms. Further, in the reception filter 1601, the corresponding parallel arms may be connected at the same or substantially the same positions in the respective series arms, and the corresponding resonators may have the same or substantially the same characteristics (e.g., the resonant frequency and the anti-resonant frequency).

The first filter 12 and the second filter 14 may be provided on one substrate, and the reception filter 1601 may be provided on another substrate. Alternatively, the first filter 12, the second filter 14, and the reception filter 1601 may be provided on a single substrate.

In the filter device according to the ninth preferred embodiment, high-power differential signals are distributed to the first filter 12 and the second filter 14 and are filtered, and the filtered signals are combined by the output converter 30 from which the resulting signal is output. Thus, the electric power handling capability of the filter device with respect to a transmission signal is increased by about two times. Unlike the filter device according to the eighth preferred embodiment, if it is not necessary to increase the electric power handling capability of the filter device with respect to a reception signal, the filter device according to the ninth preferred embodiment, which is more compact, can transmit and receive a signal while maintaining the electric power handling capability.

The preferred embodiments described above are intended to facilitate understanding of the present invention, and are not intended to be construed as limiting the present invention. The elements included in the preferred embodiments and the arrangements, materials, conditions, shapes, sizes, and the like thereof are not limited to those illustrated, and can be appropriately changed. In addition, configurations described in different preferred embodiments can be partially replaced or combined.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter device comprising:
a first filter including a first input terminal, a first output terminal, a first series arm connecting the first input terminal and the first output terminal and including a plurality of first series arm resonators, and a plurality of first parallel arms connected to the first series arm and each including a first parallel arm resonator, the first filter having a pass band in a predetermined frequency band;
a second filter including a second input terminal, a second output terminal, a second series arm connecting the second input terminal and the second output terminal and including a plurality of second series arm resonators, and a plurality of second parallel arms connected to the second series arm and each including a second parallel arm resonator, the second filter having a pass band in the predetermined frequency band;
a substrate including the first filter and the second filter; and
an inductor connected between a ground terminal and a parallel arm resonator included in at least one parallel arm of the plurality of first parallel arms and the plurality of second parallel arms.

2. The filter device according to claim 1, wherein
a first parallel arm resonator in a first parallel arm of the plurality of first parallel arms that is N-th closest to the first input terminal, where N is a natural number, and a second parallel arm resonator in a second parallel arm of the plurality of second parallel arms that is N-th closest to the second input terminal are electrically connected at a node; and
the inductor is electrically connected to the node.

3. The filter device according to claim 1, wherein the first series arm resonators, the first parallel arm resonator, the second series arm resonators, and the second parallel arm resonator are each at least one of a surface acoustic wave resonator or a bulk acoustic wave resonator.

4. The filter device according to claim 1, further comprising an output converter to receive an output difference between the first output terminal and the second output terminal and convert the received output difference into an unbalanced signal.

5. The filter device according to claim 4, wherein the output converter is provided on the substrate.

6. The filter device according to claim 4, wherein
the output converter includes a plurality of resonators; and
the plurality of resonators have a higher coupling coefficient than any of the first series arm resonators, the first parallel arm resonator, the second series arm resonators, and the second parallel arm resonator.

7. The filter device according to claim 4, wherein the output converter includes a plurality of adjacent resonators connected in series.

8. The filter device according to claim 6, wherein the output converter further includes an inductor connected in parallel to at least one of the plurality of resonators.

9. The filter device according to claim 1, further comprising an input converter to receive an unbalanced signal, convert the received unbalanced signal into a balanced signal, and input the balanced signal to the first input terminal and the second input terminal.

10. The filter device according to claim 1, wherein the first filter and the second filter are symmetrical or substantially symmetrical to each other when the substrate is viewed in plan view.

11. A filter device comprising:
a first transmission filter including a first transmission input terminal, a first antenna terminal, a first series arm connecting the first transmission input terminal and the first antenna terminal and including a plurality of first series arm resonators, and a plurality of first parallel arms connected to the first series arm and each including a first parallel arm resonator, the first transmission filter having a pass band in a first frequency band;
a second transmission filter including a second transmission input terminal, a second antenna terminal, a second series arm connecting the second transmission input terminal and the second antenna terminal and including a plurality of second series arm resonators, and a plurality of second parallel arms connected to the second series arm and each including a second parallel arm resonator, the second transmission filter having a pass band in the first frequency band;
an inductor connected between a ground terminal and a parallel arm resonator included in at least one parallel arm of the plurality of first parallel arms and the plurality of second parallel arms;
a first reception filter including a first reception output terminal, a third series arm connecting the first antenna terminal and the first reception output terminal and including at least one first longitudinally coupled resonator, and at least one of a third series arm resonator in the third series arm or a third parallel arm resonator connected between the third series arm and ground, the first reception filter having a pass band in a second frequency band; and
a second reception filter including a second reception output terminal, a fourth series arm connecting the second antenna terminal and the second reception output terminal and including at least one second longitudinally coupled resonator, and at least one of a fourth series arm resonator in the fourth series arm or a fourth parallel arm resonator connected between the fourth series arm and the ground, the second reception filter having a pass band in the second frequency band.

12. The filter device according to claim 11, wherein
a first parallel arm resonator in a first parallel arm of the plurality of first parallel arms that is N-th closest to the first input terminal, where N is a natural number, and a second parallel arm resonator in a second parallel arm of the plurality of second parallel arms that is N-th closest to the second input terminal are electrically connected at a node; and
the inductor is electrically connected to the node.

13. The filter device according to claim 11, wherein the first series arm resonators, the first parallel arm resonator, the second series arm resonators, and the second parallel arm resonator are each at least one of a surface acoustic wave resonator or a bulk acoustic wave resonator.

14. The filter device according to claim 11, wherein the first transmission filter and the second transmission filter are symmetrical or substantially symmetrical to each other.

15. A filter device comprising:
a first transmission filter including a first transmission input terminal, a first output terminal, a first series arm connecting the first transmission input terminal and the first output terminal and including a plurality of first series arm resonators, and a plurality of first parallel arms connected to the first series arm and each including a first parallel arm resonator, the first transmission filter having a pass band in a first frequency band;
a second transmission filter including a second transmission input terminal, a second output terminal, a second series arm connecting the second transmission input terminal and the second output terminal and including a plurality of second series arm resonators, and a plurality of second parallel arms connected to the second series arm and each including a second parallel arm resonator, the second transmission filter having a pass band in the first frequency band;
an inductor connected between a ground terminal and a parallel arm resonator included in at least one parallel arm among the plurality of first parallel arms and the plurality of second parallel arms;
an output converter that connects the first output terminal, the second output terminal, and an antenna terminal, receives an output difference between the first output terminal and the second output terminal, converts the received output difference into an unbalanced signal, and outputs the unbalanced signal to the antenna terminal; and
a reception filter including a reception output terminal, a third series arm connecting the antenna terminal and the reception output terminal and including at least one longitudinally coupled resonator, and at least one of a third series arm resonator in the third series arm or a third parallel arm resonator connected between the third series arm and ground, the reception filter having a pass band in a second frequency band.

16. The filter device according to claim 15, wherein
a first parallel arm resonator in a first parallel arm of the plurality of first parallel arms that is N-th closest to the first input terminal, where N is a natural number, and a second parallel arm resonator in a second parallel arm of the plurality of second parallel arms that is N-th closest to the second input terminal are electrically connected at a node; and
the inductor is electrically connected to the node.

17. The filter device according to claim 15, wherein the first series arm resonators, the first parallel arm resonator, the second series arm resonators, and the second parallel arm resonator are each at least one of a surface acoustic wave resonator or a bulk acoustic wave resonator.

18. The filter device according to claim 15, wherein the first transmission filter and the second transmission filter are symmetrical or substantially symmetrical to each other.
